(19) United States
(12) Patent Application Publication
(10) Pub. No.: US 2024/0162405 A1
(43) Pub. Date: May 16, 2024

(54) METHOD FOR MANUFACTURING DISPLAY DEVICE

(71) Applicant: DEXERIALS CORPORATION, Shimotsuke-shi, Tochigi (JP)

(72) Inventors: Daiki NODA, Shimotsuke-shi, Tochigi (JP); Reiji TSUKAO, Shimotsuke-shi, Tochigi (JP); Toshiki SHIRAIWA, Shimotsuke-shi, Tochigi (JP)

(73) Assignee: DEXERIALS CORPORATION, Shimotsuke-shi, Tochigi (JP)

(21) Appl. No.: 18/282,583

(22) PCT Filed: Mar. 23, 2022
(86) PCT No.: PCT/JP2022/013746

§ 371 Date: Sep. 18, 2023

(30) Foreign Application Priority Data
Mar. 26, 2021 (JP) 2021-054277
Mar. 23, 2022 (JP) 2022-047478

(51) Int. Cl. H01L 33/62; H01L 25/075

(52) U.S. Cl. CPC H01L 33/62; H01L 25/0753; H01L 2933/0066

(57) ABSTRACT

A display device includes a plurality of light emitting elements, a substrate, and a cured resin film. The substrate has the plurality of light emitting elements thereon. The plurality of light emitting elements form an array, each corresponding to a subpixel constituting one picture element. The cured resin film connects the plurality of light emitting elements and the substrate. The cured resin film is composed of a plurality of individual pieces and has an exposed portion in which the substrate is exposed between the plurality of individual pieces.

### TECHNICAL FIELD

The present art relates to a display device formed having an array of light emitting elements and to a method for manufacturing a display device. The present application claims priority to Japanese Patent Application No. 2021-054277 filed in Japan on Mar. 26, 2021 and to Japanese Patent Application No. 2022-047478 filed in Japan on Mar. 23, 2022, and these applications are incorporated into the present application by reference.

### BACKGROUND TECHNOLOGY

A mini LED or a micro LED (light emitting diode) display in which minute light emitting elements are formed in an array on a substrate can omit a backlight required for a liquid crystal display, can achieve a thin film display, and can widen the color gamut, increase definition, and save power to a further degree. Furthermore, micro LED displays are expected to be used as transparent displays because the light emitting elements thereof are smaller than conventional.

Patent Document 1 teaches connecting a wafer on which LEDs are disposed in subpixel units and a substrate corresponding thereto using an anisotropic conductive adhesive, and patent Document 2 teaches providing a groove between LEDs to suppress connection failure due to flow of anisotropic conductive adhesive.

However, in connections using conventional anisotropic conductive adhesive, the adhesive resin and the conductive particles remain in the pitch between LEDs, and thus it is not possible to obtain favorable light transmittance, and the aesthetics of the display device acting as a display and the light emitting device acting as a light source are impaired.

### CITATION LIST

### Patent Documents

Patent Document 1: JP 2017-157724 A
Patent Document 2: JP 2017-216321 A

### SUMMARY OF INVENTION

### Problem to be Solved by Invention

The present art is proposed in view of such conventional circumstances and provides a display device that can obtain excellent light transmittance and aesthetics and a manufacturing method for a display device.

### Means to Solve the Problem

The display device according to the present art is provided with a plurality of light emitting elements, a substrate on which the light emitting elements are formed in an array in subpixel units constituting one picture element, and a cured resin film that connects the plurality of light emitting elements and the substrate, wherein the cured resin film is composed of a plurality of individual pieces, and the substrate has an exposed portion that is exposed between the individual pieces.

The manufacturing method for a display device according to the present art is provided with an individual piece forming step for forming a plurality of individual pieces composed of a curable resin film on a base material, a bonding step for bonding the plurality of individual pieces onto a substrate, and a mounting step for mounting light emitting elements on the individual pieces bonded onto the substrate in subpixel units constituting one picture element.

The light emitting device according to the present art is provided with a plurality of light emitting elements, a substrate on which the light emitting elements are formed in an array, and a cured resin film that connects the plurality of light emitting elements and the substrate, wherein the cured resin film is composed of a plurality of individual pieces, and the substrate has an exposed portion that is exposed between the individual pieces.

The manufacturing method for a light emitting device according to the present art is provided with an individual piece forming step for removing a portion of a curable resin film formed on a base material and forming a plurality of individual pieces composed of a curable resin film on the base material, a bonding step for bonding the plurality of individual pieces onto the substrate, and a mounting step for mounting light emitting elements on the individual pieces bonded onto the substrate.

### Effect of the Invention

According to the present art, excellent light transmittance and aesthetics can be obtained by providing an exposed portion where the substrate is exposed between the individual pieces on which the light emitting elements are mounted.

### BRIEF DESCRIPTION OF THE DRAWINGS

FIG. 1 is a cross-sectional view schematically illustrating a configuration example of the display device.

FIG. 2 is a cross-sectional view schematically illustrating a configuration example of when the size of an individual piece is small with respect to the size of the light emitting element.

FIG. 3 is a cross-sectional view schematically illustrating a configuration example when the size of an individual piece is large with respect to the size of the light emitting element.

FIG. 4 is a cross-sectional view schematically illustrating a configuration example of a conventional display device.

FIG. 5(A) is a top view schematically illustrating a configuration example of a curable resin film formed on the entire surface of a base material film, and

FIG. 5(B) is a cross-sectional view schematically illustrating a configuration example of FIG. 5(A).

FIG. 6(A) is a top view schematically illustrating a configuration example of removing a portion of the curable resin film, and FIG. 6(B) is a cross-sectional view schematically illustrating a configuration example of FIG. 6(A).

FIG. 7(A) is a top view schematically illustrating a configuration example of an individual piece of the curable resin film, and FIG. 7(B) is a cross-sectional view schematically illustrating a configuration example of FIG. 7(A).

FIG. 8 is a cross-sectional view schematically illustrating a method for forming an individual piece by emitting laser light from the base material side and removing the removing portion.

FIG. 9 is a cross-sectional view schematically illustrating a state in which a light emitting element provided on the base material and an individual piece on a substrate are made to face each other.

FIG. 10 is a cross-sectional view schematically illustrating when a laser light is emitted from the substrate side and light emitting elements are transferred to predetermined positions on the substrate to form an array.

FIG. 11 is a cross-sectional view schematically illustrating when individual pieces are formed in an array on an electrode of a wiring substrate.

FIG. 12 is a cross-sectional view schematically illustrating a state in which light emitting elements are mounted on individual pieces formed in an array in electrode units.

### DESCRIPTION OF THE EMBODIMENTS

Embodiments of the present art will be described in detail below in the following order with reference to the drawings.
1. Display device
2. Manufacturing method of display device
3. Embodiments

<1. Display Device>

The display device according to the present embodiment is provided with a plurality of light emitting elements, a substrate on which the light emitting elements are formed in an array in subpixel units constituting one picture element, and a cured resin film that connects the plurality of light emitting elements and the substrate, wherein the cured resin film is composed of a plurality of individual pieces, and the substrate has an exposed portion that is exposed between the individual pieces. The exposed portion can be rephrased as a gap portion where there is no curable resin film contributing to the connection. Thus, excellent light transmittance and aesthetics can be obtained.

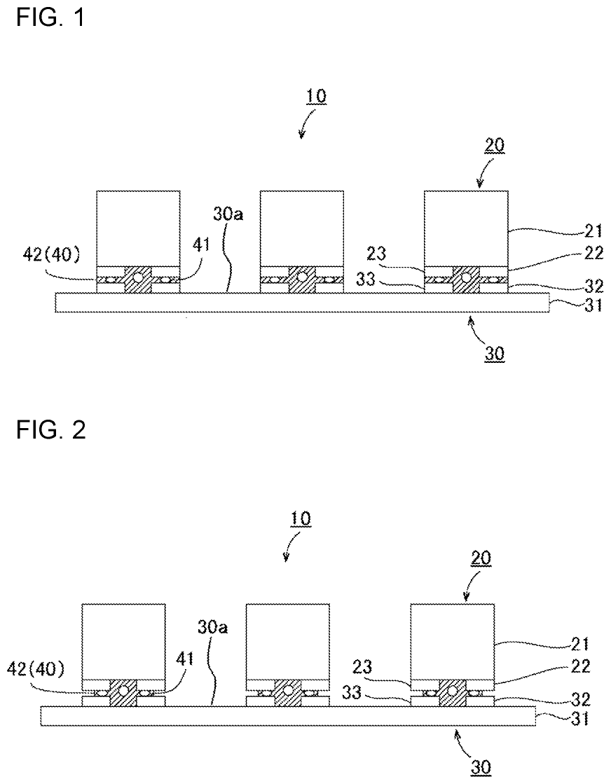

FIG. 1 is a cross-sectional view schematically illustrating a configuration example of the display device. As illustrated in FIG. 1, the display device 10 is provided with a plurality of light emitting elements 20, a substrate 30 on which the light emitting elements are formed in an array in subpixel units constituting one picture element, and a cured resin film 40 connecting the plurality of light emitting elements 20 and the substrate 30.

The light emitting element 20 is provided with a main body 21, a first conductive electrode 22, and a second conductive electrode 23, and a so-called flip chip LED having a horizontal structure, in which the first conductive electrode 22 and the second conductive electrode 23 are arranged on the same surface side, can be used. The main body 21 is provided with a first conductive clad layer made from, for example, n-GaN, an active layer made from, for example, an InₓAl_{y}Ga_{1-x-y}N layer, and a second conductive clad layer made from, for example, p-GaN, and has a so-called double heterostructure. The first conductive electrode 22 is formed on a portion of the first conductive clad layer by a passivation layer, and the second conductive electrode 23 is formed on a portion of the second conductive clad layer. When a voltage is applied across the first conductive electrode 22 and the second conductive electrode 23, carriers are concentrated in the active layer, and light emission is generated by recombination.

The size of the light emitting element 20 may be 200 μm or less, preferably less than 150 μm, more preferably less than 50 μm, and further preferably less than 20 μm. Furthermore, the thickness of the light emitting element 20 is, for example, 1 to 20 μm. In this case, the size of the light emitting element 20 is, for example, when substantially rectangular, the larger between the length or the width.

The light emitting elements 20 are formed in an array on the substrate 30 corresponding to each subpixel constituting one picture element to configure a light emitting element array. One pixel may be configured by, for example, three subpixels of R (red), G (green), and B (blue), four subpixels of RGBW (white) and RGBY (yellow), or two subpixels of RG and GB.

Examples of the method for forming the subpixels in an array include, in the case of RGB, a stripe array, a mosaic array, a delta array, and the like. The stripe array is formed by arraying the RGB in a vertical stripe shape, and high definition can be attained. Furthermore, the mosaic array has the same color of RGB disposed diagonally, and a more natural image can be obtained than with the stripe array. Moreover, the delta array forms the RGB s in a triangle array, each dot is shifted by a half pitch for each field, and a natural image display can be obtained.

Table 1 shows the estimated inter-RGB horizontal pitch, estimated chip size, and estimated electrode size for the PPI (pixels per inch) when each RGB chip is arranged in the horizontal direction. The distance between chips was assumed to be a minimum of 5 μm, and the estimated RGB distance was assumed to be the maximum when disposed at regular intervals. These were calculated as reference values for clarifying applications and examining the present art.

TABLE 1

| | | | | | | | Estimated | | | | | |
|---|---|---|---|---|---|---|---|---|---|---|---|---|
| | | | | | | | RGB | | | | | |
| | | | | | | | Horizontal | | | | Estimated | |
| | Size | | | | Pixel Pitch (μm) | | Pitch (μm) | | Estimated Chip Size | | Electrode Size | |
| | | Width | Height | | Width | Height | Min | Max | Min | Max | Min | Max |
| Application | Inch | (mm) | (mm) | ppi | (μm) | (μm) | (μm) | (μm) | (μm) | (μm) | (μm) | (μm) |
| Large | 120 | 2657 | 1494 | 40 | 635 | 635 | 15 | 212 | 10 × 20 | 207 × 417 | 7 × 7 | 150 × 150 |
| Display | | 2657 | 1494 | 100 | 254 | 254 | 15 | 85 | 10 × 20 | 80 × 160 | 7 × 7 | 60 × 60 |
| Large TV | 80 | 1771 | 996 | 80 | 318 | 318 | 15 | 106 | 10 × 20 | 101 × 202 | 7 × 7 | 70 × 70 |
| | | 1771 | 996 | 120 | 212 | 212 | 15 | 71 | 10 × 20 | 66 × 132 | 7 × 7 | 45 × 45 |
| Medium | 20 | 443 | 249 | 100 | 254 | 254 | 15 | 85 | 10 × 20 | 80 × 160 | 7 × 7 | 55 × 55 |
| Display | | 443 | 249 | 200 | 127 | 127 | 15 | 42 | 10 × 20 | 37 × 74 | 7 × 7 | 25 × 25 |
| Tablet | 10 | 221 | 125 | 200 | 127 | 127 | 15 | 42 | 10 × 20 | 37 × 74 | 7 × 7 | 25 × 25 |
| | | 221 | 125 | 400 | 64 | 64 | 15 | 21 | 10 × 20 | 16 × 32 | 7 × 7 | 10 × 10 |
| SMP | 6 | 13.26 | 7.47 | 300 | 85 | 85 | 15 | 28 | 10 × 20 | 23 × 46 | 7 × 7 | 15 × 15 |
| | | 13.26 | 7.47 | 500 | 51 | 51 | 15 | 17 | 10 × 20 | 12 × 24 | 7 × 7 | 8 × 8 |
| Watch | 2 | 3.59 | 3.59 | 300 | 85 | 85 | 15 | 28 | 10 × 20 | 23 × 46 | 7 × 7 | 15 × 15 |
| | | 3.59 | 3.59 | 500 | 51 | 51 | 15 | 17 | 10 × 20 | 12 × 24 | 7 × 7 | 8 × 8 |
| VR | 1 | 1.80 | 1.80 | 500 | 51 | 51 | 15 | 17 | 10 × 20 | 12 × 24 | 7 × 7 | 8 × 8 |
| | | 1.80 | 1.80 | 1000 | 26 | 26 | 9 | 9 | 7 × 14 | 7 × 14 | 5 × 5 | 5 × 5 |
| | | 1.80 | 1.80 | 2000 | 13 | 13 | 4 | 4 | — | — | — | — |

As shown in Table 1, it can be understood that a chip size of 10×20 μm is compatible with up to 500 PPI. Moreover, a chip size of 7×14 μm is compatible with up to 1000 PPI, and by making the chip size smaller, it is possible to realize 1000 PPI or more. Note that the chip need not necessarily be rectangular and may be square. Furthermore, the chip is not limited to a rectangle and may have a similar shape such as a diamond shape.

The substrate 30 is provided with a circuit pattern for a first conductivity type and a circuit pattern for a second conductivity type on a base material 31, and a first electrode 32 and a second electrode 33 are respectively provided at positions corresponding to, for example, the first conductive electrode on the p-side and the second conductive electrode on the n-side such that light emitting elements 20 are disposed in subpixel units constituting one picture element. Moreover, the substrate 30 forms, for example, a circuit pattern such as a data line or an address line of a matrix wiring and enables a light emitting element corresponding to each subpixel constituting one picture element to be turned on and off. Furthermore, the substrate 30 is preferably a transparent substrate, the base material 31 preferably has light transmitting properties, such as glass and PET (polyethylene terephthalate), and the circuit pattern, the first electrode 32, and the second electrode 33 are preferably transparent conductive films such as ITO (indium-tin-oxide), IZO (indium-zinc-oxide), ZnO (zinc-oxide), IGZO (indium-gallium-zinc-oxide), and the like.

A cured resin film 40 is obtained by curing a curable resin film that will be described later. The cured resin film 40 is composed of a plurality of individual pieces 42 and has an exposed portion 30a where the substrate 30 is exposed between the individual pieces 42 of the cured resin film 40. The array of the individual pieces 42 on the substrate is not particularly limited so long as an effect of light transmittance is obtained but is preferably a subpixel unit corresponding to the light emitting element 20. By arraying the individual pieces 42 in subpixel units, the exposed portion 30a can be increased, and extremely excellent light transmittance can be obtained. Moreover, a plurality of adjacent light emitting elements 20 in subpixel units may be connected by one individual piece. Thus, it is possible to increase the mounting speed (quicken the mounting efficiency) and to broaden the range of acceptable specifications depending on the substrate-side light transmittance and color conditions.

Furthermore, the individual pieces 42 made from the cured resin film 40 are preferably an adhesive film, a conductive film containing conductive particles 41, or a cured film of an anisotropic conductive film (hereinafter, an anisotropic conductive film will be described, including conductive films and anisotropic conductive films). Thus, even when a connecting site such as a solder bump is not provided on the light emitting elements 20, the plurality of light emitting elements 20 and the substrate 30 can be connected. Furthermore, when the electrodes of the light emitting elements 20 are in a protruding shape or the like and an electrical connection can be obtained with the wiring of the substrate 30, the cured resin film 40 need not contain the conductive particles 41.

The cured film of the anisotropic conductive film may have conductive particles disposed at random and is preferably configured by forming the conductive particles in an array in the plane direction. The conductive particles are formed in an array in the plane direction, and thus the particle surface density is made uniform, and the conductivity and insulation can be improved. The state in which the conductive particles are formed in an array in the plane direction may be, for example, a planar grid pattern having one or more array axes in which the conductive particles are disposed in a predetermined direction at a predetermined pitch, examples of which include an oblique grid, a hexagonal grid, a square grid, a rectangular grid, a parallel grid, and the like. Furthermore, the anisotropic conductive film may have a plurality of regions having different planar grid patterns.

The particle surface density of the cured film of the anisotropic conductive film may be suitably designed according to the electrode size of the light emitting element 40, and the lower limit of the particle surface density may be 500 pcs/mm² or more, 20,000 pcs/mm² or more, 40,000 pcs/mm² or more, or 50,000 pcs/mm² or more, and the upper limit of the particle surface density may be 1,500,000 pcs/mm² or less, 1,000,000 pcs/mm² or less, 500,000 pcs/mm² or less, or 100,000 pcs/mm² or less. Thus, even when the electrode size of the light emitting element 20 is small, excellent conductivity and insulation can be obtained. The particle surface density of the cured film of the anisotropic conductive film is that of conductive particles when formed into a film during manufacture. This is the same whether the portion measured is a randomly disposed portion or an array portion. When the particle number density is determined from the plurality of individual pieces 42, the particle surface density may be determined from the surface area excluding the space between the individual pieces 42 based on the surface area including the individual pieces 42 and the space, and the number of particles. It may be inappropriate to express the individual pieces by a number density, and it may be appropriate to express this by the occupancy surface area ratio of the particle in one individual piece, or the particle diameter and the inter-particle center distance, and the number.

The number of conductive particles per individual piece may be suitably designed according to the electrode size of the light emitting element 40, and the lower limit is, for example, 2 or more, preferably 4 or more, and more preferably 10 or more, and the upper limit is 6,000 or less, preferably 500 or less, and more preferably 100 or less.

The average transmittance of the visible light after the individual pieces have been placed (provided) on the substrate is preferably 20% or more, more preferably 35% or more, and further preferably 50% or more. Thus, a display device having excellent light transmittance and aesthetics can be obtained. Even when the substrate is not transparent, individual pieces can be adhered to a glass blank or a transparent substrate for evaluation, and the average transmittance can be determined by using the individual pieces as a reference (Ref). The average transmittance of visible light is lower when the light emitting element is provided. When a light emitting element is mounted, measurement is performed in a non-lighted state. The average transmittance of visible light may be measured using, for example, an ultraviolet visible spectrophotometer.

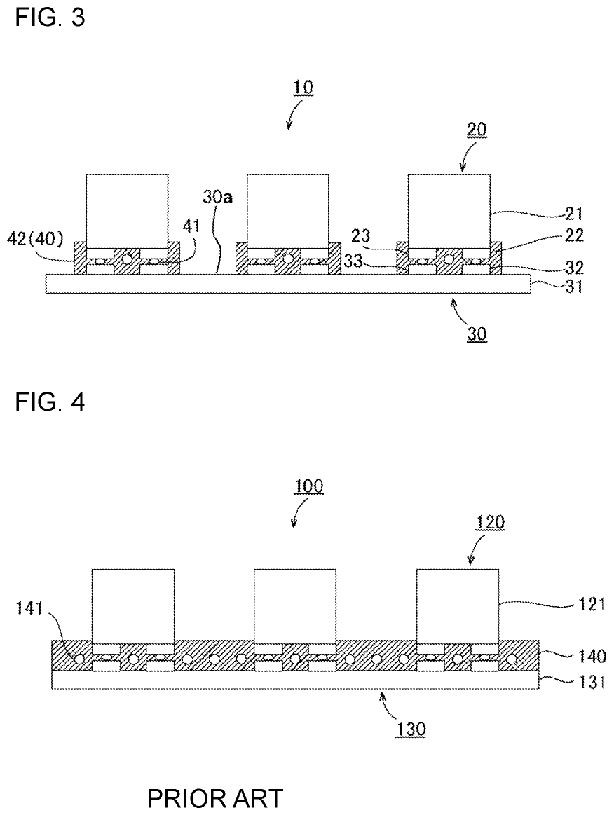

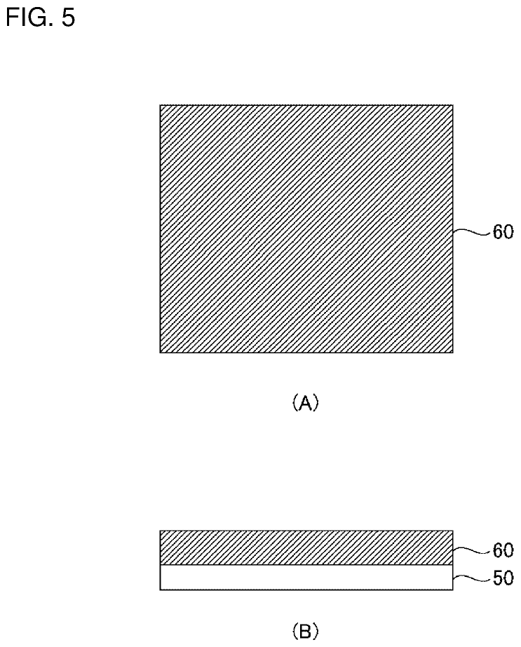

FIG. 2 is a cross-sectional view schematically illustrating a configuration example of when the size of an individual piece is small with respect to the size of the light emitting element, FIG. 3 is a cross-sectional view schematically illustrating a configuration example of when the size of an individual piece is large with respect to the size of the light emitting element, and FIG. 4 is a cross-sectional view schematically illustrating a configuration example of a conventional display device.

Insofar as conductivity can be obtained, the size of the individual pieces of the cured resin film 40 relative to the size of the light emitting element 20 may be smaller than the size of the light emitting element 20 as illustrated in FIG. 2. Furthermore, so long as the light transmissivity effect of the display device can be obtained, the individual pieces of the cured resin film 40 may be disposed so as to be present not only directly below the light emitting element but also in a peripheral portion, as illustrated in FIG. 3

The amount of protrusion of individual pieces from the light emitting element is preferably less than 30 μm, more preferably less than 10 μm, and further preferably less than 5 μm. Furthermore, when the individual pieces do not protrude, the amount of protrusion may be zero or negative. Thus, excellent light transmittance can be obtained compared to the configuration example of a conventional display device 100 where a cured resin film 140 is provided on the entire surface of a substrate 130 illustrated in FIG. 4. Note that the amount of protrusion of an individual piece from the light emitting element 20 is the maximum value of the distance from the peripheral edge of the light emitting element 20 to the peripheral edge of the individual piece. Alternatively, when one side of the light emitting element 20 is 1, the amount of protrusion of the individual pieces is 0.3 or less, preferably 0.1 or less.

According to the display device of the present embodiment, due to having the exposed portion 30a where the substrate 30 is exposed between the individual pieces of the cured resin film 40, excellent light transmittance, conductivity, and insulation that could not be achieved by conventional connections of ACP, ACF, NCF and the like can be obtained, and a transparent display having high luminance and high definition can be obtained.

In the embodiment described above, an example is given of a display device acting as a display in which the light emitting elements 20 are formed in an array in subpixel units, but the present art is not limited thereto and may be applied to, for example, a light emitting device acting as a light source. The light emitting device is provided with a plurality of light emitting elements, a substrate on which the light emitting elements are formed in an array, and a cured resin film that connects the plurality of light emitting elements and the substrate, wherein the cured resin film is composed of a plurality of individual pieces, and the substrate has an exposed portion that is exposed between the individual pieces. According to such a light emitting device, the number of chips per wafer increases due to the light emitting element 20 having a very small size, and thus cost can be reduced, and industrial advantages such as a thinner light emitting device and energy conservation can be obtained.

<2. Manufacturing Method of Display Device>

The manufacturing method for a display device according to the present embodiment is provided with an individual piece forming step for forming a plurality of individual pieces composed of a curable resin film on a base material, a bonding step for bonding the plurality of individual pieces onto a substrate, and a mounting step for mounting light emitting elements on the individual pieces bonded onto the substrate in subpixel units constituting one picture element. Thus, since the exposed portion where the substrate is exposed is formed between the individual pieces, excellent light transmittance can be obtained.

Furthermore, in the manufacturing method of an adhesive film according to the present embodiment, a removing portion of a curable resin film formed on a base material is irradiated with laser light, and individual pieces composed of a curable resin film are formed on the base material. Moreover, the adhesive film according to the present embodiment is provided with a base material and a plurality of individual pieces formed on the base material and composed of a curable resin film, and a distance between the individual pieces is 3 μm or more and 3000 μm or less. Examples of the base material include PET (polyethylene terephthalate), OPP (oriented polypropylene), PMP (poly-4-methylpentene-1), PTFE (polytetrafluoroethylene), glass, and the like. Furthermore, a base material in which at least the surface on the curable resin film side is subject to a peel-off treatment with, for example, a silicone resin, may be preferably used. The adhesive film may be wound as a reel or may be a sheet body (leaflet) or a plate.

An individual piece forming step (A) for forming a plurality of individual pieces, an adhering step (B) for adhering the plurality of individual pieces onto a substrate, and a mounting step (C) for mounting light emitting elements will be described below with reference to FIGS. 5 to 11.

[Individual Piece Forming Step (A)]

The method for forming the individual pieces is not particularly limited and, for example, a method of forming by removing a portion of the curable resin film using a laser, cutting, or the like, a method of forming using a printing method, an inkjet method, or the like may be used. Processing after forming a film on the base material in advance is preferable from the perspective of flexibility in shape design and ease in the process of disposing conductive particles.

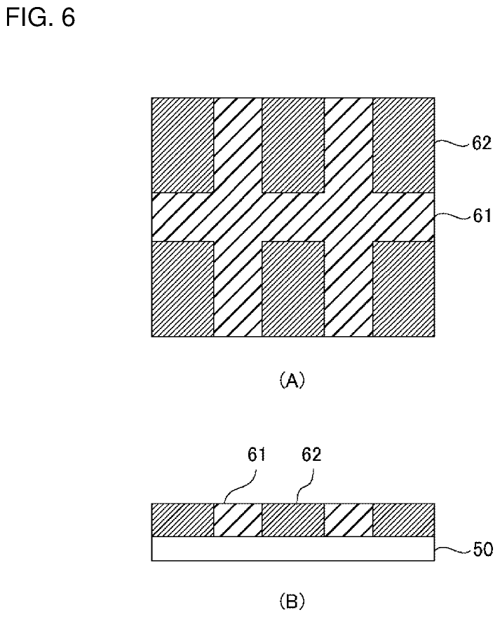

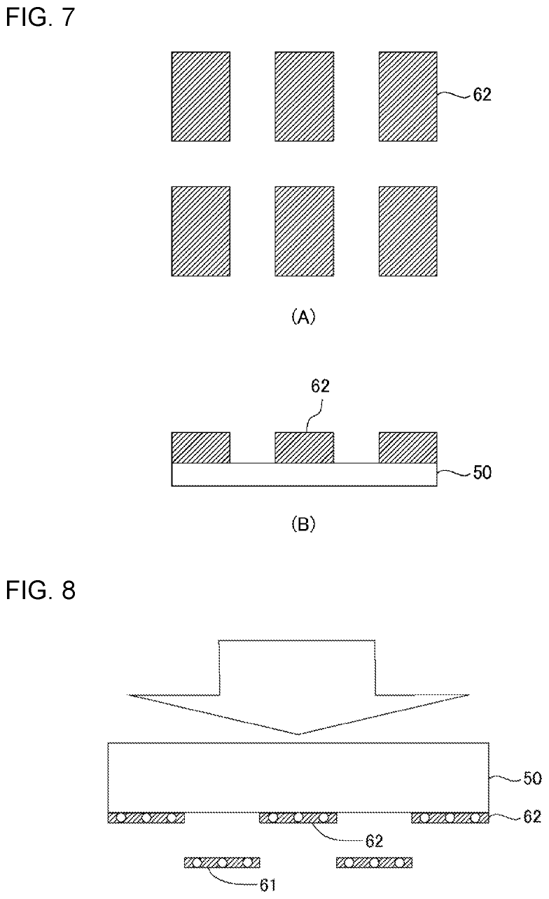

FIG. 5 to FIG. 7 are diagrams illustrating examples where a portion of the curable resin film is removed by a laser to form individual pieces, FIG. 5(A) is a top view schematically illustrating a configuration example of a curable resin film formed on the entire surface of a base material film, FIG. 5(B) is a cross-sectional view schematically illustrating a configuration example of FIG. 5(A), FIG. 6(A) is a top view schematically illustrating a configuration example of removing a portion of the curable resin film, FIG. 6(B) is a cross-sectional view schematically illustrating a configuration example of FIG. 6(A), FIG. 7(A) is a top surface view schematically illustrating a configuration example of an individual piece of the curable resin film, and FIG. 7(B) is a cross-sectional view schematically illustrating a configuration example of FIG. 7(A).

First, a curable resin film 60 is formed on a base material 50 as illustrated in FIGS. 5(A) and 5(B) to prepare a curable resin film substrate. The curable resin film 60 is formed by using, for example, a known method such as mixing, coating, and drying.

(Base Material)

The base material 50 may be a material that is transmissive for a laser beam, and in particular, it is preferable that the quartz glass has a high light transmittance over all wavelengths. Furthermore, when forming the individual pieces by a printing method, an inkjet method, or the like, PET (Polyethylene Terephthalate), PC (Polycarbonate), polyimide, or the like may be used as the base material 50.

(Curable Resin Film)

The curable resin film 60 is not particularly limited so long as it is cured by energy such as heat, light, or the like, and it may be suitably selected from a thermosetting binder, a photocurable binder, a thermosetting and photocurable binder, and the like. As a specific example, a thermosetting binder containing a film forming resin, a thermosetting resin, and a curing agent will be described. The thermosetting binder is not particularly limited, and examples include a thermal anion polymerization type resin composition containing an epoxy compound and a thermal anion polymerization initiator, a thermal cation polymerization type resin composition containing an epoxy compound and a thermal cation polymerization initiator, and a thermal radical polymerization type resin composition containing a (meth)acrylate compound and a thermal radical polymerization initiator. Note that the meaning of (meth)acrylate compound also includes both an acrylic monomer (oligomer) and a methacrylic monomer (oligomer).

Among these thermosetting binders, the thermosetting resin preferably contains an epoxy compound, and the curing agent is preferably a thermal cationic polymerization initiator. Thus, the curing reaction when forming the individual pieces using the laser beam can be suppressed, and the individual pieces can be rapidly cured by heat during thermocompression bonding. A thermal cationic polymerization type resin composition containing a film forming resin, an epoxy compound, and a thermal cationic polymerization initiator will be described as specific examples below.

The film forming resin preferably corresponds to, for example, a high molecular weight resin having an average molecular weight of 10,000 or more, and from the perspective of film formability, preferably has an average molecular weight of about 10,000 to 80,000. Examples of film forming resins include various resins such as butyral resins, phenoxy resins, polyester resins, polyurethane resins, polyester urethane resins, acrylic resins, polyimide resins, and the like, and these can be used alone or in combination of two or more types. Among these, it is preferable to use a butyral resin from the perspective of film formation state, connection reliability, and the like. The content of the film forming resin is preferably 20 to 70 parts by mass, more preferably 30 to 60 parts by mass or less, and further preferably 45 to 55 parts by mass, with respect to 100 parts by mass of the thermosetting binder.

The epoxy compound is not particularly limited so long as it is an epoxy compound having one or more epoxy groups in the molecule, and it may be, for example, a bisphenol A type epoxy resin, a bisphenol F type epoxy resin, or the like or may be a urethane modified epoxy resin. Among these, a hydrogenated bisphenol A glycidyl ether may be preferably used. Specific examples of a hydrogenated bisphenol A glycidyl ether include, for example, the product named “YX8000” manufactured by Mitsubishi Chemical Corporation. The content of the epoxy compound is preferably 30 to 60 parts by mass, more preferably 35 to 55 parts by mass or less, and further preferably 35 to 45 parts by mass, with respect to 100 parts by mass of the thermosetting binder.

A known thermal cationic polymerization initiator of an epoxy compound may be used as the thermal cationic polymerization initiator. For example, a known iodonium salt, sulfonium salt, phosphonium salt, ferrocene, or the like that generates an acid that can cationically polymerize a cationically polymerizable compound via heat can be used. Among these, an aromatic sulfonium salt exhibiting good latent properties with respect to temperature may be preferably used. Specific examples of an aromatic sulfonium salt based polymerization initiator include, for example, the product named “SI-60L” manufactured by Sanshin Chemical Industry Co., Ltd. The content of the thermal cationic polymerization initiator is preferably 1 to 20 parts by mass, more preferably 5 to 15 parts by mass or less, and further preferably 8 to 12 parts by mass, with respect to 100 parts by mass of the thermosetting binder.

Note that rubber components, inorganic fillers, silane coupling agents, diluting monomers, fillers, softening agents, colorants, flame retardants, thixotropic agents, and the like may be added as necessary as other additives to be added to the thermosetting binder.

The rubber components are not particularly limited so long as they are elastomers having high cushioning (shock absorption), and specific examples include acrylic rubber, silicone rubber, butadiene rubber, polyurethane resin (polyurethane based elastomer), and the like. Silica, talc, titanium oxide, calcium carbonate, magnesium oxide, and the like may be used as the inorganic filler. The inorganic filler may be used alone or in combination of two or more types.

The curable resin film 60 is preferably an anisotropic conductive film further containing conductive particles. Conductive particles used in known anisotropic conductive films may be suitably selected and used. Examples include metal particles such as nickel, copper, silver, gold, palladium, and solder, metal-coated resin particles where the surfaces of resin particles such as polyamide, polybenzoguanamine, or the like are coated with a metal such as nickel or gold, and the like. Thus, conduction can be achieved even when a connection portion such as a solder bump is not provided on the chip component.

The anisotropic conductive film is preferably configured by arraying conductive particles in the plane direction. The conductive particles are formed in an array in the plane direction, and thus the particle surface density is made uniform, and the conductivity and insulation can be improved. Furthermore, the anisotropic conductive film may be configured so as to have an unevenly distributed region where conductive particles are unevenly distributed at a position corresponding to an electrode and a region where no conductive particles are present at other positions. From the perspective of capturing, the unevenly distributed region is preferably a range of 0.8 times or more the electrode size, preferably 1.0 times or more, and for reduction of the conductive particles, 1.2 times or less, preferably 1.5 times or less, the electrode size. The removing portion may also be used for quality control, inspection applications, and the like.

Similarly to the cured film, the particle surface density of the anisotropic conductive film may be suitably designed according to the electrode size of the light emitting element 40, and the lower limit of the particle surface density may be 500 pcs/mm² or more, 20,000 pcs/mm² or more, 40,000 pcs/mm² or more, or 50,000 pcs/mm² or more, and the upper limit of the particle surface density may be 1,500,000 pcs/mm² or less, 1,000,000 pcs/mm² or less, 500,000 pcs/mm² or less, or 100,000 pcs/mm² or less. Thus, even when the electrode size of the light emitting element 20 is small, excellent conductivity and insulation can be obtained. The particle surface density of the cured film of the anisotropic conductive film is that of the array portion of conductive particles when formed into a film during manufacture. When the particle number density is determined from the plurality of individual pieces, the particle surface density may be determined from the surface area excluding the space between the individual pieces based on the surface area including the individual pieces and the spaces, and the number of particles.

The particle diameter of the conductive particles is not particularly limited, but the lower limit of the particle diameter is preferably 1 μm or more, and the upper limit of the particle diameter is preferably, for example, 50 μm or less, and more preferably 20 μm or less, from the perspective of the capturing efficiency of the conductive particles in the connecting structure. Depending on the size of the electrode, there may be cases where less than 3 μm, preferably less than 2.5 μm, is required. Note that the particle diameter of the conductive particles may be a value measured using an image type particle size distribution meter (for example, FPIA-3000: manufactured by Malvern). This number of particles is preferably 1,000 or more, and more preferably 2,000 or more.

The lower limit of the thickness of the curable resin film 60 may be, for example, 60% or more of the particle diameter of the conductive particles and may be 90% or more in order to be compatible with a relatively small particle diameter, but it is preferably 1.3 times or more of the conductive particle diameter or 3 μm or more. Furthermore, the upper limit of the thickness of the connecting film may be, for example, 20 μm or less, or three times or less, preferably two times or less, the particle diameter of the conductive particles. Furthermore, the curable resin film 60 may be laminated with an adhesive layer or glue layer that does not contain conductive particles, and the number of layers and the laminated surface thereof may be suitably selected according to the target or purpose. Furthermore, the same resin as the curable resin film 60 may be used as the insulating resin for the adhesive layer or glue layer. The thickness of the film may be measured using a known micrometer or digital thickness gauge. The thickness of the film may be determined by measuring, for example, ten or more locations and taking the average.

The tackiness of the front and back surfaces of the curable resin film 60 according to the probe method may be set to 1.0 kPa (0.1 N/cm²) or greater on at least one of the front and back surfaces when measured in conditions that, for example, the probe pressing speed is 30 mm/min, the pressure force is 196.25 gf, the pressurization time is 1.0 sec, the peel rate is 120 mm/min, and the measurement temperature is s 23° C.±5° C., and it is preferably set to 1.5 kPa (0.15 N/cm²) or more, more preferably higher than 3 kPa (0.3 N/cm²). In the measurement, for example, by adhering one surface of the curable resin film 60 of 3 cm×3 cm or more to a glass blank (for example, a thickness of 0.3 mm), the tackiness of the other surface may be measured. When at least one of the front and back surfaces of the curable resin film 60 has a tackiness in the range described above, the adhesion of the curable resin film 60 to the base material 50 can be maintained, and in the adhering step (B) described later, the adhesion of the plurality of individual pieces to the substrate 30 can be maintained.

Next, as illustrated in FIGS. 6(A) and 6(B), the removing portion 61 of the curable resin film 60 is irradiated with laser light, and as illustrated in FIGS. 7(A) and 7(B), individual pieces 62 composed of the curable resin film are formed on the base material 50.

The dimensions (length×width) of the individual pieces 62 are suitably set according to the dimensions of the light emitting element 20, which is a chip component, and the ratio of the surface area of the individual pieces 62 to the surface area of the light emitting element 20 is preferably from 0.5 to 5.0, more preferably from 0.5 to 4.0, and further preferably from 0.5 to 2.0. Furthermore, the thickness of the individual pieces 62 is preferably 2 to 10 μm, more preferably 3 to 8 μm, and further preferably 4 to 6 μm or less. The dimensions of the individual pieces are all preferably the same, but a plurality of types may be present in order to increase the degree of freedom in designing the connection structure. Thus, a connection structure having excellent light transmittance, conductivity, and insulation which could not be achieved by conventional connections such as ACP, ACF, NCF, and adhesive can be obtained.

Furthermore, the distance between the individual pieces 62 forming an array at a predetermined position of the base material 50 is preferably 3 μm or more, more preferably 5 μm or more, and further preferably 10 μm or more. Furthermore, the upper limit of the distance between the individual pieces is preferably 3,000 μm or less, more preferably 1,000 μm or less, and further preferably 500 μm or less. When the distance between the individual pieces is too small, it is difficult to obtain excellent light transmittance and aesthetics, and when the distance between the individual pieces is too large, it is difficult to obtain a high PPI display device.

FIG. 8 is a cross-sectional view schematically illustrating a method for forming an individual piece 62 by emitting laser light from the base material side and removing the removing portion 61. For example, a LIFT (LIFT: laser induced forward transfer) device may be used to remove the removing portion 61. The LIFT device is provided with, for example, a telescope for making a pulse laser beam emitted from a laser device parallel, shaping optics for uniformly shaping a spatial intensity distribution of the pulse laser beam that has passed through the telescope, a mask for passing the pulse laser beam shaped by the shaping optics through a predetermined pattern, a field lens positioned between the shaping optics and the mask, and a projection lens for reducing and projecting the laser beam that has passed through the pattern of the mask onto a donor substrate, and a curable resin film substrate, which is the donor substrate, is held on a donor stage.

For example, an excimer laser for oscillating a laser beam having a wavelength of 180 nm to 360 nm may be used as the laser device. The oscillation wavelengths of the excimer laser are, for example, 193, 248, 308, and 351 nm and may be suitably selected from among these oscillation wavelengths according to the light absorption of the material of the curable resin film 60. Furthermore, when a release material is provided between the base material 50 and the curable resin film 60, it may be suitably selected according to the light absorption of the material of the release material.

A mask has a pattern in which an array of windows of a predetermined size is formed at a predetermined pitch such that a projection on a boundary surface between the base material 50 and the curable resin film 60 is a desired array of laser light. The mask is patterned by, for example, chrome plating, where a window portion that is not chrome-plated transmits a laser beam, and a portion that is chrome-plated blocks the laser beam.

Outgoing light from the laser device is made incident on telescope optics and propagated to subsequent shaping optics. Because the laser light immediately before entering the shaping optics is adjusted by the telescope optics so as to become substantially parallel light at every position within the movement range of the X axis of the donor stage, the laser light always enters the shaping optics at substantially the same size and the same angle (perpendicular).

The laser light that has passed through the shaping optics becomes incident on the mask via a field lens that constitutes image-side telecentric reduction projection optics in combination with the projection lens. The laser light that has passed through the mask pattern changes its propagation direction vertically downward due to an epi-illumination mirror and becomes incident on the projection lens. The laser light exiting the projection lens becomes incident via the base material 50 side and is accurately projected in a reduced size of the mask pattern onto a prescribed position of the curable resin film 60 formed on a surface (lower surface) thereof.

Laser energy intensity in laser irradiation is not particularly limited and may be suitably selected according to the purpose, but 5% or more and 100% or less is preferable, and 5% or more and 50% or less is more preferable. The laser energy intensity is an intensity expressed by an output percentage when a laser irradiation intensity of 10,000 mJ/cm² is set to 100. For example, a laser energy intensity of 10% means a laser irradiation intensity of 1,000 mJ/cm².

Furthermore, the number of times the laser is emitted is not particularly limited and may be suitably selected according to the purpose, but 1 to 10 times is preferable. The total laser irradiation intensity in laser irradiation is preferably 500 mJ/cm² or more and 10,000 mJ/cm² or less, more preferably 1,000 mJ/cm² or more and 5,000 mJ/cm² or less. Here, the total laser irradiation intensity is the irradiation intensity calculated as the sum total of the laser irradiation intensity of n times at the time of laser irradiation. Here, “n” indicates the number of times the laser is emitted.

A device that can be ablate with a pulse laser such as LMT-200 (manufactured by Toray Engineering), C.MSL-LLO1.001 (manufactured by Takano), or DFL7560L (manufactured by DISCO) may be used as a laser irradiation device for removing the anisotropic conductive layer.

By using such a LIFT device, shock waves are generated in the curable resin film 60 irradiated with the laser light on the boundary surface between the base material 50 and the curable resin film 60, the removing portion 61 can be removed from the base material 50 by peeling, and the individual pieces 62 of the curable resin film 60 can be highly accurately and efficiently arrayed on the base material 50.

Note that, depending on the method, “curling” may occur on an individual piece 62 when the removing portion 61 on the base material 50 is removed. Connection failure may occur when a portion where a resin layer is doubled due to curling is adhered to an electrode portion. Furthermore, distortion of the shape of the individual pieces 62 may also be a factor in poor adhesion. It is preferable that the curled portion of the individual piece 62 is less than 20% of a prescribed surface area of the individual piece 62 set in advance. Furthermore, when the individual piece 62 is adhered on the substrate 30, the peripheral edge of the individual piece 62 may also be “curled,” and in this case, the curled portion of the individual piece 62 is preferably less than 20% of the prescribed surface area of the individual piece 62 that is set in advance. Thus, connection failure and adhesion failure can be suppressed. The shape of the individual piece 62 set in advance is preferably rectangular. When the shape of the individual piece 62 is distorted, the dimensions can be found by converting the film surface area into a rectangular shape. The dimension of one side of the individual piece 62 can be applied to an approximation of the original shape. Furthermore, when the individual piece 62 is curled, it may be approximated to a rectangular shape based on the shape where the individual piece is not curled. When a plurality of individual pieces 62 are present, it may be calculated by setting a prescribed surface area of the individual pieces 62 that is not curled to 100%. These can be found using an observation method that will be described below.

[Adhering Step (B)]

In the adhering step (B), a plurality of individual pieces 62 arrayed on the substrate 50 are adhered on the substrate 30. The adhering method of the individual pieces 62 is not particularly limited, and examples include a method of temporarily adhering the individual pieces 62 from the base material 50 to the substrate 30 to transfer.

In the individual piece forming step (A), when the individual pieces are formed on the base material 50 in subpixel units, it is preferable that the individual pieces 62 on the base material 50 are transferred onto the substrate 30 in the adhering step (B). By aligning the base material 50 and the substrate 30 and then transferring, the individual pieces 62 can be arrayed on the substrate 30 in subpixel units. When the size of the substrate 30 is larger than the size of the base material 50, the individual pieces 62 on the base material 50 can be arrayed in subpixel units in the screen area of the substrate 30 by transferring onto the substrate 30 a plurality of times.

The average transmittance of the visible light of the substrate 30 to which the plurality of individual pieces 62 are adhered after the adhering step (B) is preferably 20% or more, more preferably 35% or more, and further preferably 50% or more. Thus, a display device having excellent light transmittance and aesthetics can be obtained.

[Mounting Step (C)]

In the mounting step (C), first, the light emitting elements 20 are mounted on the individual pieces 62 of the substrate 30. The method of mounting the light emitting elements 20 on the substrate 30 is not particularly limited, but examples include a method of directly transferring and disposing the light emitting elements 20 from the wafer substrate to the substrate 30 by a laser lift-off method (LLO method) and a method of transferring and disposing the light emitting element 20 from a transfer substrate to the substrate 30 using a transfer substrate to which the light emitting elements 20 are adhered in advance.

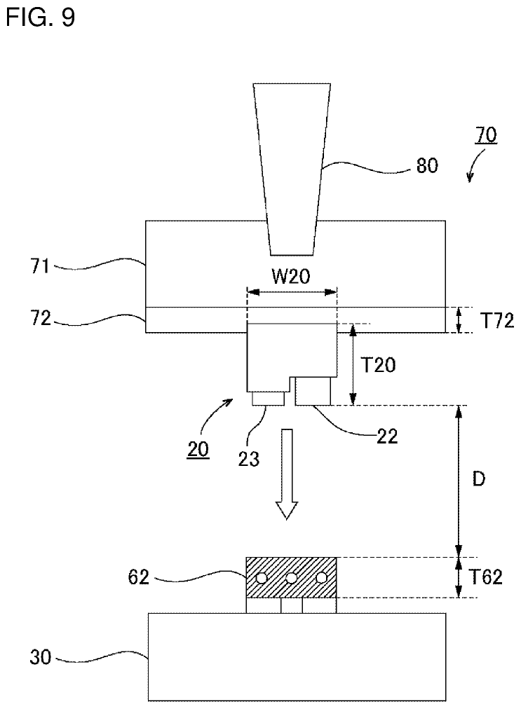

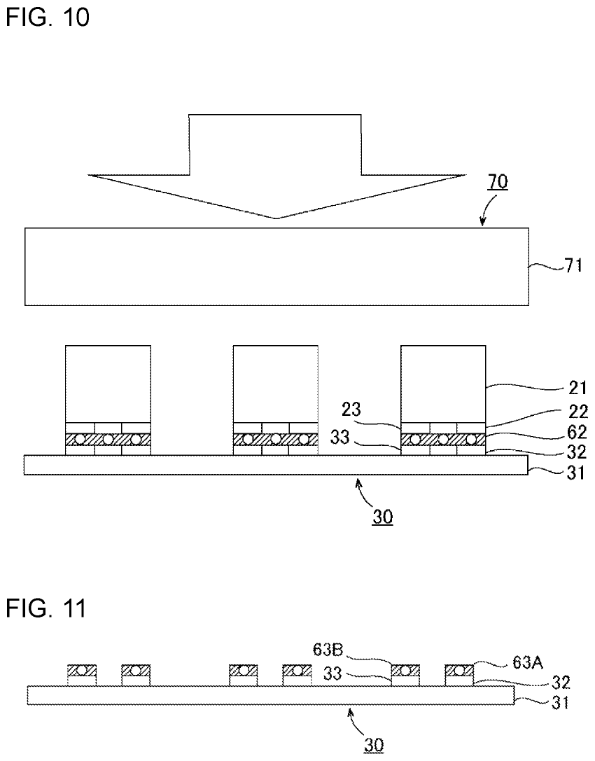

A step for depositing the light emitting elements on the individual pieces by emitting laser light will be described below with reference to FIGS. 9 and 10. FIG. 9 is a cross-sectional view schematically illustrating a state in which a light emitting element provided on a base material and an individual piece on a substrate are made to face each other, and FIG. 10 is a cross-sectional view schematically illustrating when a laser light is emitted from the substrate side and light emitting elements are transferred to predetermined positions on the substrate to form an array.

As illustrated in FIG. 9, first, a chip component substrate 70 provided with the light emitting elements 20 and the individual pieces 62 composed of the curable resin film on the substrate 30 are made to face each other.

The chip component substrate 70 is provided with a base material 71, a release material 72, and the light emitting elements 20, and the light emitting elements 20 are adhered to a surface of the release material 72. The substrate 71 may be made of a material that is transmissive for a laser beam, and in particular, it is preferable that made of a quartz glass that has a high light transmittance over all wavelengths. The releasing material 72 may absorb the wavelength of the laser beam, generates a shock wave by irradiation with the laser beam, and bounces the light emitting element 20 toward the substrate 30 side. For example, polyimide may be used as the release material 72.

A distance D between the light emitting element 20 and the individual piece 62 is, for example, 10 to 100 μm. A width W20 of the light emitting element 20 is preferably less than 150 μm, more preferably less than 50 μm, and further preferably less than 20 μm. Furthermore, a thickness T20 of the light emitting element 20 is, for example, 1 to 20 μm. A thickness T12 of the release material 72 is, for example, 1 μm or more. Dimensions (length×width) of the individual pieces 62 are suitably set according to the dimensions of the light emitting elements 20, and surface area ratio of the individual pieces 62 to the light emitting elements 20 is preferably from 0.5 to 5.0. Furthermore, a thickness T62 of the individual pieces 62 is preferably 2 to 10 μm, more preferably 3 to 8 μm, and further preferably 4 to 6 μm or less. A distance D between the light emitting elements 20 and the individual pieces 62 can be observed and confirmed by, for example, an optical microscope, a laser microscope, a white microscope, or the like. The conductive particle diameter, the array shape of the conductive particles, the distance between the conductive particles, and the like may be similarly found.

Next, as illustrated in FIG. 10, a laser light 80 is emitted from the substrate 71 side, and the light emitting elements 20 are transferred on to the individual pieces 62 of the substrate 30 to form an array. For example, the LIFT device described above may be used for transferring the light emitting elements 20, and the chip component substrate 70, which is the donor substrate, is held in the donor stage, and the substrate 30, which is the receptor substrate, is held in the receptor stage. The laser light 80 that has passed through the mask pattern becomes incident via the base material 71 side and is accurately projected on a predetermined position of the release material 72 formed on the surface (bottom surface) thereof at the reduced size of the mask pattern. At the boundary surface between the base material 71 and the release material 72, an impact wave is generated in the release material 72 by irradiation with the laser beam 80, and the plurality of light emitting elements 20 peel from the base material 71, are lifted toward the substrate 30, and are deposited on the individual pieces 62 of the substrate 30. Thus, the occurrence of defects such as misalignment, deformation, destruction, and detachment of the light emitting elements 20 can be suppressed, the light emitting elements 20 can be transferred and arrayed with high precision and high efficiency, and tact time can be shortened.

Next, the light emitting elements 20 arrayed at the prescribed position of the substrate 30 are thermocompression bonded via the individual pieces 62. A thermocompression bonding method used in a known curable resin film may be suitably selected and used as a method for thermocompression bonding the light emitting elements to the substrate 30. The thermocompression bonding conditions are, for example, a temperature of 150° C. to 260° C., a pressure of 1 MPa to 60 MPa, and a time of 5 to 300 seconds. A cured resin film is formed by curing the curable resin film. Furthermore, when the conductive particles are solder particles, they may be connected by reflow.

According to the method for manufacturing the display device according to the present embodiment, the light emitting elements 20 may be connected on the substrate in a state such that the exposed portion 30a where the substrate 30 is exposed between the individual pieces of the cured resin film 40 is provided. Thus, excellent light transmittance, conductivity, and insulation which could not be achieved by conventional connections of ACP, ACF, NCF, adhesive, and the like can be obtained, and a transparent display having high luminance and high definition can be obtained.

In the embodiment described above, an example is given of a manufacturing method of a display device acting as a display in which the light emitting elements 20 are formed in an array in subpixel units, but the present art is not limited thereto and may be applied to, for example, a manufacturing method of a light emitting device acting as a light source. The manufacturing method of a light emitting device is provided with an individual piece forming step for removing a portion of a curable resin film formed on a base material and forming a plurality of individual pieces composed of a curable resin film on the base material, an adhering step for adhering the plurality of pieces onto the substrate, and a mounting step for mounting light emitting elements on an individual piece adhered to the substrate. According to such a manufacturing method of a light emitting device, cost reduction can be achieved, and industrial advantages such as a thinner light emitting device and energy conservation can be obtained.

Furthermore, in the embodiment described above, in the individual piece forming step (A), the individual pieces are formed in light emitting element units, that is, subpixel units, but the present invention is not limited thereto and may be formed, for example, in units of electrodes of the light emitting elements.

When the individual pieces are formed in units of the electrodes of the light emitting elements, the dimensions (length×width) of the individual pieces are suitably set according to the dimensions of the electrodes of the light emitting element, and in the same manner as when the individual pieces are formed in the unit of the light emitting element, the ratio of the surface area of the individual pieces to the surface area of the electrodes is preferably from 0.5 to 5.0, more preferably from 0.5 to 4.0, and further preferably from 0.5 to 2.0. Furthermore, the thickness of the individual pieces is preferably 2 to 10 μm, more preferably 3 to 8 μm or less, and further preferably 4 to 6 μm or less.

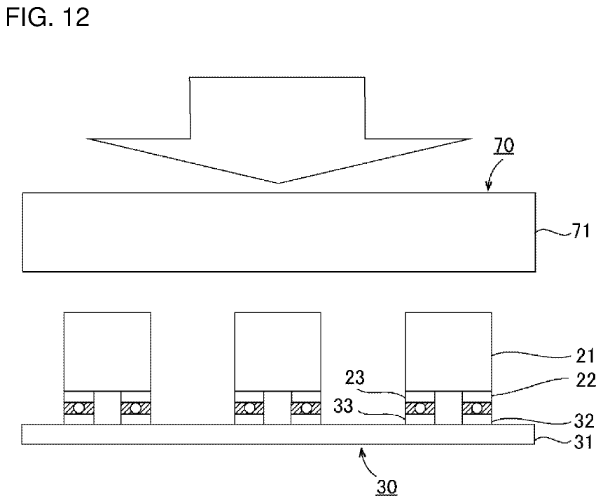

FIG. 11 is a cross-sectional view schematically illustrating when individual pieces are formed in an array on an electrode of a wiring substrate, and FIG. 12 is a cross-sectional view schematically illustrating a state in which light emitting elements are mounted on individual pieces formed in an array in electrode units. In the individual piece forming process (A), when the individual pieces are formed in the unit of the electrodes of the light emitting elements 20, the individual pieces 63 are adhered onto the electrodes of the substrate 30 in the adhering step (B). That is, as illustrated in FIG. 11, a first individual piece 63A and a second individual piece 63B are respectively adhered to a first electrode 32 and a second electrode 33 respectively corresponding to, for example, a first conductive electrode 22 on a p side and a second conductive electrode 23 on the n side of the light emitting element 20. Then, as illustrated in FIG. 12, in the mounting step (C), the light emitting elements 20 are mounted on the individual pieces 63 arrayed in electrode units on the wiring substrate 30. Thus, the transparency of the display device can be further improved.

In the individual piece forming step (A), when the individual pieces are formed by removing a portion of the curable resin film by laser, pretreatment may be conducted on the curable resin film in order to efficiently remove an unnecessary portion of the curable resin film. Examples of preprocessing include cuts in the shape of individual pieces in light emitting element units or electrode units and lattice-shaped cuts where a plurality of longitudinal cuts and a plurality of lateral cuts intersect. The cuts can be formed by a mechanical method, a chemical method, a laser, or the like. Note that the cuts need not be so deep as to reach the base material, and they may be half cuts. Thus, the occurrence of curling of individual pieces can be suppressed.

Furthermore, in the adhering step (B), the plurality of individual pieces 62 of the light emitting element unit or the plurality of individual pieces 63 of the electrode unit arrayed on the base material 50 may be transferred to the substrate 30 using the LIFT device described above. By using the LIFT device, a shock wave is generated in an individual piece irradiated with a laser beam on a boundary surface between the base material and the individual piece, the individual pieces are peeled from the base material and lifted toward the substrate 30, and the individual pieces are deposited at prescribed positions of the substrate 30 with high accuracy. Thus, the tact time can be shortened.

Furthermore, using the LIFT device described above, the plurality of individual pieces 62 in light emitting element units or the plurality of individual pieces 63 of in electrode units arrayed on the base material 50 may be transferred to the light emitting elements 20 arrayed on the chip component substrate 70, and the light emitting elements to which the individual pieces were transferred may be re-transferred onto the substrate 30. Thus, the tact time can be shortened.

### EXAMPLES

### 3. Examples

In the present examples, mounting was performed by changing the dimensions of the connecting material relative to the dimensions of the chip, and visible light transmittance, the amount of overhang of the adhesive, and the amount of alignment deviation before and after mounting were evaluated. Furthermore, the conduction resistance and the insulation resistance were also evaluated. Note that the present art is not limited to these examples.

### Example 1

A resin film was obtained by mixing, coating, and drying (60° C.—3 min) such that 50 wt % of a polyvinyl butyral resin (product name: KS-10, manufactured by Sekisui Chemical Industry Co., Ltd.), 40 wt % of a hydrogenated bisphenol A glycidyl ether (product name: YX8000, manufactured by Mitsubishi Chemical Corporation), and 10 wt % of a cationic polymerization initiator (product name: SI-60L, manufactured by Sanshin Chemical Industry Co., Ltd.).

Conductive particles (average particle diameter of 2.2 μm, resin core metal coated fine particles, Ni plating having a thickness of 0.2 μm, manufactured by Sekisui Chemical Industry Co., Ltd.) were pressed and transferred onto the obtained resin film such that the conductive particles substantially match one interface of the resin film using the method described in JP 6187665, and an anisotropic conductive film having a thickness of 4.0 μm and a particle surface density of 58,000 pcs/mm 2 was obtained. The alignment of the conductive particles in a plan view of the anisotropic conductive film was configured to be a hexagonal lattice array.

A portion of the anisotropic conductive film on a glass is removed by laser ablation, and individual pieces of a 15×30 μm (surface area ratio of 1.0) anisotropic conductive film having a thickness of 4.0 μm were formed in a prescribed array on the glass. The laser irradiation conditions are as follows.
Laser type: YAG Laser
Laser wavelength: 266 nm
Laser energy intensity: 10%
Number of laser irradiations: 1 time

Then, after the individual pieces were temporarily adhered at prescribed positions on the glass substrate and arrayed such that 15×30 μm microchips that imitate a micro LED in an surface area of 1.5×1.5 cm were equivalent to 110 ppi (chip occupancy surface area ratio: 2.46%, total number of chips: 12,288), and the microchips were thermocompression bonded (temperature of 170° C.-pressure of 30 MPa-time of sec) via the individual pieces to obtain a package.

### Example 2

A package was obtained in the same way as in example 1 other than forming individual pieces of a 10.6×21.2 μm (surface area ratio of 0.5) anisotropic conductive film having a thickness of 4.0 μm in a prescribed array on a glass.

### Example 3

A package was obtained in the same way as in example 1 other than forming individual pieces of a 33.5×67.1 μm (surface area ratio of 5.0) anisotropic conductive film having a thickness of 4.0 μm in a prescribed array on a glass.

### Example 4

A package was obtained in the same way as in example 1 other than, after obtaining an anisotropic conductive film having a thickness of 6.0 μm and a particle surface density of 58,000 pcs/mm², forming individual pieces of a 15×30 μm anisotropic conductive film having a thickness of 6.0 μm in a prescribed array on a glass.

### Example 5

A package was obtained in the same way as in example 1 other than, after obtaining an anisotropic conductive film having a thickness of 4.0 μm and a particle surface density of 100,000 pcs/mm², forming individual pieces of a 15×30 μm anisotropic conductive film having a thickness of 4.0 μm in a prescribed array on a glass.

### Example 6

An anisotropic conductive film having a thickness of 4.0 μm was obtained by mixing conductive particles (the same conductive particles as in example 1) into a resin mixture of 50 wt % of a polyvinyl butyral resin (product name: KS-10, manufactured by Sekisui Chemical Industry Co., Ltd.), 40 wt % of a hydrogenated bisphenol A glycidyl ether (product name: YX8000, manufactured by Mitsubishi Chemical Corporation), and 10 wt % of a cationic polymerization initiator (product name: SI-60L, manufactured by Sanshin Chemical Industry Co., Ltd.) such that the particle surface density was 58,000 pcs/mm², coating, and drying (60° C.—3 min). Then, a package was obtained in the same way as in example 1 other than forming individual pieces of a 15×30 μm anisotropic conductive film having a thickness of 4.0 μm in a prescribed array on a glass.

### Comparative Example 1

2 vol % of conductive particles (the same conductive particles as in example 1) and 10 vol % of titanium oxide were dispersed in a resin composition that was mixed to 95 wt % of a hydrogenated bisphenol A glycidyl ether (product name: YX8000, manufactured by Mitsubishi Chemical Corporation) and 5 wt % of an aluminum chelate latent curing agent, thereby obtaining an anisotropic conductive paste.

Then, after applying the anisotropic conductive paste to the entire surface of a glass to obtain an anisotropic conductive film having a thickness of 4.0 μm, 15×30 μm microchips that imitate a micro LED were thermocompression bonded (temperature 170° C.-pressure 30 MPa-time 30 sec) via the anisotropic conductive film in an area of 1.5×1.5 cm such that the microchips were equivalent to 110 ppi.

### Comparative Example 2

An anisotropic conductive film having a thickness of 4.0 μm was obtained by mixing conductive particles (the same conductive particles as in example 1) into a resin mixture of 50 wt % of a polyvinyl butyral resin (product name: KS-10, manufactured by Sekisui Chemical Industry Co., Ltd.), 40 wt % of a hydrogenated bisphenol A glycidyl ether (product name: YX8000, manufactured by Mitsubishi Chemical Corporation), and 10 wt % of a cationic polymerization initiator (product name: SI-60L, manufactured by Sanshin Chemical Industry Co., Ltd.) such that the particle surface density was 58,000 pcs/mm², coating, and drying (60° C.—3 min). Then, after adhering the anisotropic conductive film to the entire surface of a glass to obtain an anisotropic conductive film having a thickness of 4.0 μm, 15×30 μm microchips that imitate a micro LED were heat pressed (temperature 170° C.-pressure 30 MPa-time 30 sec) via the anisotropic conductive film in an area of 1.5×1.5 cm such that the microchips were equivalent to 110 ppi.

### Comparative Example 3

A resin film and a substrate having conductive particles (the same conductive particles as example 1) arrayed in a prescribed pattern were adhered, and the conductive particles were transferred to the resin film to obtain an anisotropic conductive film having a thickness of 4.0 μm and particle surface density of 58,000 pcs/mm². Then, after adhering the anisotropic conductive film to the entire surface of a glass to obtain an anisotropic conductive film having a thickness of 4.0 μm, 15×30 μm microchips that imitate a micro LED were heat pressed (temperature 170° C.-pressure 30 MPa-time 30 sec) via the anisotropic conductive film in an area of 1.5×1.5 cm such that the microchips were equivalent to 110 ppi.

[Evaluation of Visible Light Transmittance]

A transmittance measurement device (UV-2450 manufactured by Shimadzu Corporation, JIS Z 8729, light source Type-C, viewing angle 2°) was used to measure average transmittance of visible light (wavelengths of 400 to 700 nm) for quartz glass (thickness of 0.4 mm) provided with an array of individual pieces (Examples 1 to 6), an anisotropic conductive film (Comparative Examples 2 and 3), or an anisotropic conductive film made by coated with anisotropic conductive paste (Comparative Example 1). The visible light transmittance was evaluated by grading as A to D below according to the average transmittance of visible light. It is desirable that the evaluation of the visible light transmittance be graded C or higher.
A: 50% or more
B: 35% or more and less than 50%
C: 20% or more and less than 35%
D: Less than 20%

[Evaluation of Amount of Overhang]

After mounting microchips that imitate a micro LED, the external appearance was observed from the microchip side using a metal microscope, and adhesive overhanging from the microchip was measured. The amount of overhang was evaluated by grading as A to D below according to the amount of overhang of the adhesive. It is desirable that the evaluation of the amount of overhang be graded C or higher.
A: Less than 5 μm
B: 5 μm or more and less than 10 μm
C: 10 μm or more and less than 30 μm
D: 30 μm or more

[Evaluation of Alignment Deviation Before and After Mounting]

After temporarily securing microchips imitating a micro LED to an anisotropic conductive film on a glass, the external appearance was observed using a metal microscope, and after mounting the chip, the external appearance was again observed using the metal microscope from the microchip side. Then, it was checked whether alignment deviation occurred between before and after mounting, and when chip deviation did occur, the deviation amount was measured. The chip deviation was evaluated by grading as A to D below according to the amount of chip deviation. It is desirable that the evaluation of the chip deviation be graded C or higher.
A: Less than 0.1 μm
B: 0.1 μm or more and less than 1 μm
C: 1 μm or more and less than 2 μm
D: 2 μm or more

[Evaluation of Conduction Resistance and Insulation Resistance]

An IC chip for evaluation (external shape: 5 mm×5 mm, thickness: 0.15 mm, electrode size: 15 μm×30 μm, electrode: Au, protrusion height: 10 μm) was thermocompression bonded (temperature of 170° C.-pressure of 30 MPa-time of 30 sec) onto a glass substrate for evaluation (external shape: 28 mm×65 mm, thickness: 0.5 mm, electrode: ITO/MoNb wiring) using each of the connecting materials of Examples 1 to 6 and Comparative Examples 1 to 3, and a connected body was obtained.

The conduction resistance of the connected body was measured by a four-terminal method. The conduction resistance was evaluated by grading as A to D below according to the conduction resistance value. It is desirable that the evaluation of the conduction resistance be graded C or higher.
A: Less than 30 Ω
B: 30Ω or more and less than 100 Ω
C: 100Ω or more and less than 300 Ω
D: 300Ω or more

An insulation space between electrodes (7 μm) was measured at 100 locations, and 10Ω or less was counted as a short. The insulation resistance was evaluated by grading as A to D below according to the number of shorts. It is desirable that the evaluation of the conduction resistance be graded C or higher.
A: 0 shorts
B: 1 short
C: 2 shorts
D: 3 or more shorts

Table 1 shows the evaluation results for visible light transmittance for Examples 1 to 6 and Comparative Examples 1 to 3, the amount of overhang of adhesive, the amount of deviation of the chip, the conduction resistance, and the insulation resistance.

TABLE 2

| | | | | | | | Comparative | Comparative | Comparative |
|---|---|---|---|---|---|---|---|---|---|
| | Example 1 | Example 2 | Example 3 | Example 4 | Example 5 | Example 6 | Example 1 | Example 2 | Example 3 |
| Sample form | Individual | Individual | Individual | Individual | Individual | Individual | Paste | Film | Film |
| before mounting | pieces | pieces | pieces | pieces | pieces | pieces | | | |
| Particle state in | Array | Array | Array | Array | Array | Random | Random | Random | Array |
| plane direction | | | | | | | | | |
| Conductive particle | 2.2 | 2.2 | 2.2 | 2.2 | 2.2 | 2.2 | 2.2 | 2.2 | 2.2 |
| diameter [μm] | | | | | | | | | |
| Particle surface | 58K | 58K | 58K | 58K | 100K | 58K | | 58K | 58K |
| density [pcs/mm²] | | | | | | | | | |
| Thickness [μm] | 4.0 | 4.0 | 4.0 | 6.0 | 4.0 | 4.0 | 4.0 | 4.0 | 4.0 |
| ACF surface | 1.0 | 0.5 | 5.0 | 1.0 | 1.0 | 1.0 | >5.0 | >5.0 | >5.0 |
| area/chip | | | | | | | | | |
| surface area | | | | | | | | | |
| Evaluation of | A | A | B | B | A | A | C | D | D |
| visible light | | | | | | | | | |
| transmittance | | | | | | | | | |
| Evaluation of | A | A | C | A | A | A | D | D | D |
| amount of overhang | | | | | | | | | |
| Evaluation of | A | A | A | C | A | A | C | A | A |
| chip deviation | | | | | | | | | |
| after mounting | | | | | | | | | |
| Evaluation of | A | C | A | A | A | C | D | C | A |
| conduction | | | | | | | | | |
| resistance | | | | | | | | | |
| Evaluation of | A | A | A | A | D | D | D | D | A |
| insulation | | | | | | | | | |
| resistance | | | | | | | | | |

As shown in Table 1, Comparative Example 1, which used an ACP, had a property of being a paste and thus had a large resin flow during mounting, and therefore, ACP adhesive resin and conductive particles were present within the pitch of the microchips, which interfered with the transmission of light, and thus favorable transmittance was not obtained. Furthermore, in Comparative Example 1, which used an ACP, the electrode size of the IC chip for evaluation was small, and thus it was not possible to obtain a favorable evaluation for the conduction resistance and the insulation resistance.

Comparative Examples 2 and 3, which used an ACF, adhered the ACF to the entire surface of a glass substrate to mount microchips, and thus, similarly to Comparative Example 1, the ACF adhesive resin and conductive particles were present within the pitch of the microchips, which interfered with the transmission of light, and thus favorable transmittance was not obtained. Furthermore, in Comparative Example 2, which used a randomly arrayed ACF, the electrode size of the IC chip for evaluation was small, and thus it was not possible to obtain a favorable evaluation for the conduction resistance and the insulation resistance.

Conversely, Examples 1 to 6, which used individual pieces of anisotropic conductive film, had an exposed portion where the glass substrate was exposed within the pitch of the microchip, and therefore a high transmittance of visible light was obtained, and an evaluation having a favorable amount of overhang as well was obtained. Furthermore, Examples 1 to 4, which used individual pieces having particle densities of 40,000 to 80,000 pcs/mm² in the array obtained a favorable evaluation of insulation resistance.

### REFERENCE SIGNS LIST

10 display device, 20 light emitting element, 21 main body, 22 first conductive electrode, 23 second conductive electrode, 30 substrate, 30a exposed portion, 31 base material, 32 first electrode, 33 second electrode, 40 cured resin film, 41 conductive particle, 42 individual piece, 50 base material, 60 curable resin film, 61 removing portion, 62 individual piece, 63 individual piece, 70 chip component substrate, 71 base material, 72 release material, 80 laser light, 100 display device, 120 light emitting element, 121 main body, 130 substrate, 131 base material, 140 cured resin film, 141 conductive particle

1. A display device, comprising:
a plurality of light emitting elements;
a substrate having the plurality of light emitting elements thereon, the plurality of light emitting elements forming an array, each corresponding to a subpixel constituting one picture element; and
a cured resin film connecting the plurality of light emitting elements and the substrate,
wherein the cured resin film is composed of a plurality of individual pieces and has an exposed portion in which the substrate is exposed between the plurality of individual pieces.

2. The display device according to claim 1, wherein the individual pieces form an array in subpixel units on the substrate.

3. The display device according to claim 1, wherein an amount of protrusion of the individual piece from the light emitting element is less than 30 μm.

4. The display device according to claim 1, wherein the substrate is a transparent substrate.

5. The display device according to claim 1, wherein a size of the light emitting element is less than 200 μm.

6. The display device according to claim 1, wherein the cured resin film contains conductive particles therein, and the conductive particles are arranged in an array in a plane direction.

7. A method of manufacturing the display device according to claim 1, the method comprising:
forming a curable resin film on a base material;
removing a portion of the curable resin film to form a plurality of individual pieces composed of the curable resin film on the base material;
adhering the plurality of individual pieces onto a substrate; and
mounting light emitting elements on the plurality of individual pieces adhered to the substrate, so that each light emitting element is mounted on each individual piece and corresponds to a subpixel constituting one picture element, to obtain the display device.

8. The method according to claim 7, wherein the plurality of individual pieces are formed on the base material so that each individual piece corresponds to the subpixel, and
the plurality of individual pieces on the base material are adhered onto the substrate by transferring.

9. The method according to claim 7, wherein the substrate is a transparent substrate.

10. The method according to claim 7, wherein the average transmittance of visible light of the substrate after the plurality of individual pieces are adhered is 20% or more.

11. The method according to claim 7, wherein a size of the light emitting element is less than 200 μm.

12. The method according to claim 7, wherein a ratio of surface area of the plurality of individual pieces to surface area of the light emitting elements is from 0.5 to 5.0.

13. The method according to claim 7, wherein the curable resin film contains conductive particles therein, and the conductive particles are arranged in an array in a plane direction.

14. A light emitting device, comprising:
a plurality of light emitting elements;
a substrate having the plurality of light emitting elements arrayed thereon; and
a cured resin film connecting the plurality of light emitting elements and the substrate,
wherein the cured resin film is composed of a plurality of individual pieces and has an exposed portion in which the substrate is exposed between the plurality of individual pieces.

15. A method of manufacturing the light emitting device according to claim 14, the method comprising:
forming a curable resin film on a base material;
removing a portion of the curable resin film to form a plurality of individual pieces composed of the curable resin film on the base material;
adhering the plurality of individual pieces onto a substrate; and
mounting light emitting elements on the plurality of individual pieces adhered to the substrate, so that each light emitting element is mounted on each individual piece, to obtain the light emitting device.

16. An adhesive film comprising:
a base material; and
a plurality of individual pieces composed of a curable resin film formed on the base material,
wherein a distance between the plurality of individual pieces is 3 μm or more and 3,000 μm or less.

17. A method of manufacturing the adhesive film according to claim 16, the method comprising:
forming a curable resin film on a base material;
irradiating a removing portion of the curable resin film with laser light to form a plurality of individual pieces composed of the curable resin film formed on the base material, to obtain the adhesive film.
